(19) United States
(12) Patent Application Publication
(10) Pub. No.: US 2017/0233509 A1
(43) Pub. Date: Aug. 17, 2017

(54) LUMINESCENT ETHYLENE-BASED COPOLYMER, PHOTOVOLTAIC ENCAPSULANT COMPOSITIONS AND SOLAR CELL MODULE USING SAME

(71) Applicant: NITTO DENKO CORPORATION, Osaka (JP)

(72) Inventors: Hisanari ONOUCHI, Osaka (JP); Sadahiro NAKANISHI, Osaka (JP); Shoichi KAWAMITSU, Osaka (JP)

(21) Appl. No.: 15/504,392

(22) PCT Filed: Jul. 16, 2015
(86) PCT No.: PCT/JP2015/070387

§ 371 Date: Feb. 16, 2017

(30) Foreign Application Priority Data
Aug. 25, 2014 (JP) 2014-170369

(51) Int. Cl. C08F 210/02; H01L 31/028; H01L 31/048; H01L 31/055; C09K 11/06; C09B 69/10

(52) U.S. Cl. CPC C08F 210/02; C09K 11/06; C09B 69/109; H01L 31/0481; H01L 31/055; H01L 31/028

(57) ABSTRACT

An object of the present invention is to provide a luminescent ethylene-based copolymer which causes no problem of the shift or bleeding-out of a fluorescent body, which has a high workability, desired optical properties and a good light stability and which is easily handled in a kneading step; and a encapsulant composition for a solar cell, using this copolymer. Another object of the invention is to provide a encapsulant layer, for a solar cell, which is formed using the photovoltaic encapsulant composition to cause no problem of the shift or bleeding-out of a fluorescent body in this layer and to have desired optical properties and a good light stability; and a photoelectromotive module having this layer. The copolymer is a luminescent ethylene-based copolymer including, as a monomer component, a fluorescent dye compound having an unsaturated bond.

### TECHNICAL FIELD

The present inventions relate to a luminescent ethylene-based copolymer which is much suitable for solar cells to have a favorable absorption wavelength and an excellent light stability when used in and a method of producing the luminescent ethylene-based copolymer, e.g., a wavelength-converting encapsulant composition for solar cells; a wavelength-converting encapsulant layer for solar cells (such as a wavelength-converting film or a wavelength-converting sheet), and a solar cell module each using the polymeric compound. The photovoltaic encapsulant layer has a potential of attaining a remarkable enhancement of the sunlight collecting efficiency of a photoelectromotive device or a solar cell device.

### BACKGROUND ART

The use of solar energy supplies a promising energy alternate for conventional fossil fuels. In recent years, therefore, a great attention has been paid to the development of devices capable of converting solar energy to electricity, for example, the development of a photoelectromotive device (also known as a solar cell) and others. Mature photoelectromotive devices of some different types have been developed. Examples thereof include silicon devices, III-V and II-VI PN junction devices, copper-indium-gallium-selenium (CIGS) thin film devices, organic sensitizer devices, organic thin film devices, and cadmium-sulfide/cadmium-telluride (CdS/CdTe) thin film devices. Details of these devices can be found out in documents and others (see, for example, Non-Patent Document 1). However, about the photoelectric conversion efficiency of many of these devices, there has still been a room for improvement. For many researches, the development of a technique for improving this efficiency is a theme which is being tackled.

In order to improve the conversion efficiency, investigations have been made about solar cells having such a wavelength-converting function that wavelengths not contributing to photoelectric conversion (for example, ultraviolet wavelengths), out of wavelengths of rays radiated into the cells, are converted to wavelengths contributing to photoelectric conversion (see, for example, Patent Document 2). According to the investigations, a suggestion is made about a method of mixing a fluorophore powder with a resin material to form an emission panel.

Wavelength-converting inorganic media to be used in photoelectromotive devices and solar cells have been so far disclosed. However, reports have hardly been made about researches on the use of a photoluminescent organic medium in a photoelectromotive device for improving the efficiency of the device. In contrast to inorganic media, organic material is typically more inexpensive, and is easier to use. From this matter, attention is paid to the use of organic media in the point that the selection of organic material becomes a better economical selection.

When the fluorescent body powder is used, a method is adopted in which, e.g., a kneader or extruder is generally used to knead, into a encapsulant sheet, the fluorescent body added to a material for the encapsulant sheet while the fluorescent body is heated and melted. In a case where in this kneading step the added fluorescent body is low in compatibility with the resin, or is high in melting point, it is necessary to perform the kneading under severer conditions such that the kneading temperature is heightened or the kneading period is made long. In such a case, there may be caused inconveniences such that during the kneading, the temperature of the resin rises so that the crosslinking agent (organic peroxide), which starts to react when heated, is decomposed in the kneading. In the kneading machine, the added fluorescent body may adhere onto the inside of the machine. Thus, labor is required for cleaning up the machine. It has also been made evident that the added fluorescent body unfavorably diffuses to bleed out so that the concentration of the fluorescent body in the resin may be decreased. It is supposed that when the fluorescent body is used, particularly, for solar cells, the solar cells are used outdoors over a long term of 20 years or longer. It is therefore an especially important theme to improve the fluorescent body in stability over such a period, or long-term storage stability.

### PRIOR ART DOCUMENTS

### Patent Documents

Patent Document 1: US-A-2009/0151785

Patent Document 2: JP-H07-142752

### SUMMARY OF THE INVENTION

### Problems to be Solved by the Invention

In light of such a situation, an object of the present invention is to provide a luminescent ethylene-based copolymer which causes no problem of the shift or bleeding-out of a fluorescent body, which has a high workability, desired optical properties and a good light stability and which is easily handled in a kneading step; and a encapsulant composition for a solar cell, using this copolymer.

Another object of the present invention is to provide a encapsulant layer, for a solar cell, which is formed using the encapsulant composition for a solar cell described just above to cause no problem of the shift or bleeding-out of a fluorescent body in this layer and to have desired optical properties and a good light stability; and a photoelectromotive module having this layer.

### Means for Solving the Problems

In order to solve the above-mentioned problems, the inventors have made eager investigations to find out that the above-mentioned objects can be attained by a luminescent ethylene-based copolymer described below, and a encapsulant composition for a solar cell, using this copolymer. Thus, the present invention has been accomplished.

The luminescent ethylene-based copolymer of the present invention comprises, as a monomer component, a fluorescent dye compound having an unsaturated bond.

The luminescent ethylene-based copolymer of the present invention comprises, as a monomer component, a fluorescent dye compound having an unsaturated bond. Thus, the copolymer can be a copolymer which does not cause a problem that the fluorescent body shifts or bleeds out, which has a high workability, desired optical properties (such as a high quantum yield) and a good light stability (chemical and physical stability), and which is easily handled in a kneading step. There is not easily generated an uneven dispersion of a substance, as caused particularly in the case of using, e.g., a fluorescent body powder. Furthermore, while the copolymer or a copolymer-including composition is kneaded to be melted, reaction of any crosslinking agent therein can also be restrained from being caused by the melting through heating. Additionally, the following problem is also largely prevented or is not caused: when, e.g., fluorescent body powder is used, the fluorescent body powder migrates inside the encapsulant layer or bleeding-out from the encapsulant layer. About the expression of the effects and advantages, it is presumed at present that a mechanism described below contributes mainly to the expression. However, it is not specified that the expression is indispensably via the mechanism. It is presumed about the luminescent ethylene-based copolymer that: the fluorescent dye compound thereof, which effects as a fluorescent dye, is chemically linked to a polymeric structural moiety of the copolymer by the copolymerization, so that the fluorescent dye compound is restrained from being shifted inside the copolymer or inside the encapsulant layer; consequently, the fluorescent dye compound can be restrained over a long term from being migrated inside the layer or being discharged outside the layer (long-term reliability).

In general, for example, a dye compound having a heterocyclic structure may be poor in solubility because of the planarity or crystallinity thereof. However, the luminescent ethylene-based copolymer of the present invention is a polymeric body so as to be excellent in workability. In the case of using a dye compound low in solubility or dye compound high in crystallinity, it may be difficult to cleaning away the dye compound when the production of the copolymer is changed to another production, or when the apparatus concerned is subjected to maintenance. However, the luminescent ethylene-based copolymer of the invention can easily be kneaded or formed into a film even in any apparatus. Thus, the above-mentioned inconveniences can also be overcome. Furthermore, the luminescent ethylene-based copolymer is an ethylene-based copolymer so as to be also excellent in transparency. When a novel compound having a low molecular weight is put into the market, it is usually necessary to make individual tests, a registration, and others on the basis of the Chemical Substance Control Law of Japan; however, the polymeric fluorescent dye compound of the invention is a polymeric body to be handled as a compound to be restrictedly taken into any living body. Thus, the tests and the others can be made with less procedural and horal burden. Furthermore, the luminescent ethylene-based copolymer has properties and advantageous effects as described above; thus, the copolymer is suitable particularly for solar cells.

In the luminescent ethylene-based copolymer of the present invention, the unsaturated bond is preferably a carbon-carbon double bond. The use of the carbon-carbon double bond makes it easy to convert copolymer-starting materials to the ethylene-based copolymer.

It is preferred that the fluorescent dye compound is bonded through a covalent bond to the luminescent ethylene-based copolymer of the present invention. According to a bond weak in bonding energy, such as a coordinate bond, it is difficult that a substance having the bond has a sufficiently high endurance. However, the bonding through the covalent bond can produce a encapsulant composition having long-term reliability and chemical stability.

In the luminescent ethylene-based copolymer of the present invention, the copolymeric composition of the fluorescent dye compound is preferably from 0.01 to 20% by weight. This structure makes it easy that the copolymer gives both of long-term reliability and a wavelength-converting function for a encapsulant composition with a good balance.

In the luminescent ethylene-based copolymer of the present invention, the fluorescent dye compound preferably has a triazole skeleton, carbazole skeleton, thiadiazole skeleton, spiropyran skeleton, acridine skeleton, xanthene skeleton, imidazole skeleton, oxazole skeleton, quinoxaline skeleton, or thiazole skeleton. This structure makes it easy that the copolymer gives both of long-term reliability and a wavelength-converting function for a encapsulant composition with a good balance.

The luminescent ethylene-based copolymer of the present invention preferably comprises, as a monomer component, at least one of an α-olefin and vinyl acetate. This structure makes it easy with a higher certainty that the copolymer gives workability, light transmissivity, long-term reliability and a wavelength-converting function for a encapsulant composition with a good balance.

It is also preferred that the luminescent ethylene-based copolymer of the present invention has a maximum absorption wavelength in a wavelength range from 300 to 410 nm. When the copolymer has the maximum absorption wavelength in this wavelength range, the copolymer makes it possible to convert more effectively incident rays having wavelengths which are not easily used (or not usable) for photoelectric conversion by a solar cell into a wavelength range which can be photoelectrically converted by the solar cell or the like. In the invention, the maximum absorption wavelength denotes a wavelength at which the absorbance of the light absorbed by this compound (copolymer) is a maximum value, and is measurable as a wavelength at which the copolymer shows a maximum absorption peak in an ultraviolet absorption spectrum thereof.

It is also preferred that the luminescent ethylene-based copolymer of the present invention has a maximum fluorescence emission wavelength in a wavelength range from 400 to 560 nm. When the copolymer has the maximum fluorescence emission wavelength in this wavelength range, the copolymer makes it possible to convert more effectively incident rays having wavelengths which are not easily used (or not usable) for photoelectric conversion by a solar cell into a wavelength range which can be photoelectrically converted by the solar cell. In the invention, the maximum fluorescence emission wavelength denotes a wavelength of a ray showing a maximum emission intensity, out of light rays emitted from the compound (copolymer), and is measurable as a wavelength at which the copolymer shows a maximum emission peak in a fluorescence emission spectrum thereof.

The encapsulant composition of the present invention for a solar cell comprises the above-defined luminescent ethylene-based copolymer. This photovoltaic encapsulant composition may be a composition comprising, as a main component thereof, the luminescent ethylene-based copolymer. The photovoltaic encapsulant composition may be a composition comprising an optically transparent resin matrix besides the luminescent ethylene-based copolymer. The photovoltaic encapsulant composition may be a composition in which the above-defined luminescent ethylene-based copolymer obtained by copolymerization of the fluorescent dye compound in a proportion of 5% or 10% by mole is used together with a different matrix resin. When the solar cell module includes the photovoltaic encapsulant composition, rays having shorter wavelengths than wavelengths which a solar cell absorbs can be efficiently red-shifted into the range of longer wavelengths which the solar cell can use for photovoltaics. Consequently, a broader-range spectrum of solar energy can be converted into electricity. Moreover, the photovoltaic encapsulant composition has a large fluorescence quantum efficiency and a good workability. Thus, the present invention can gain a photovoltaic encapsulant composition supplying an excellent photoelectric conversion effect, advantageously for the production process of this composition and costs. Furthermore, the photovoltaic encapsulant composition of the invention receives, as an input, at least one photon having a first wavelength to give, as an output, at least one photon having a second wavelength longer (larger) than the first wavelength. In this process, the photovoltaic encapsulant composition expresses an original function of a photovoltaic encapsulant composition. Furthermore, even when the photovoltaic encapsulant composition is subjected to a storage test over a long period, the luminescent ethylene-based copolymer dispersed in the composition does not undergo migration, bleeding-out nor any other inconvenience. Thus, the present invention can easily give a stable and uniform encapsulant composition (and layer) having long-term reliability. In such a way, the encapsulant composition is particularly suitable for solar cells.

When the encapsulant composition is rendered a mixture of plural resins, the wording “AA comprises, as a main component thereof, a resin BB” denotes a case where the resin BB is included at a ratio by weight of 50% or more of the AA. The ratio by weight is more preferably 70% or more by weight, even more preferably 90% or more by weight.

Furthermore, the encapsulant layer of the present invention for a solar cell is formed, using the above-defined photovoltaic encapsulant composition. By the formation using the composition, the composition is turned to a photovoltaic encapsulant layer which has desired optical properties (such as a high quantum yield) and a good light stability (chemical and physical stability). In more detail, the photovoltaic encapsulant composition has a large fluorescence quantum efficiency and a good workability; thus, the composition can give a photovoltaic encapsulant layer supplying an excellent photoelectric conversion effect, advantageously for a production process of the layer and costs. Moreover, the photovoltaic encapsulant layer of the present invention receives, as an input, at least one photon having a first wavelength to give, as an output, at least one photon having a second wavelength longer (larger) than the first wavelength. In this process, this layer expresses an original function of a photovoltaic encapsulant layer. Furthermore, even when the photovoltaic encapsulant layer is subjected to a storage test over a long period, the luminescent ethylene-based copolymer dispersed in the encapsulant layer does not undergo migration, bleeding-out nor any other inconvenience. Thus, the present invention provides a stable and uniform encapsulant layer having long-term reliability. In such a way, the encapsulant layer is particularly suitable for solar cells.

The solar cell module of the present invention includes a encapsulant layer, for a solar cell, formed using the above-defined photovoltaic encapsulant composition. Since the solar cell module has this photovoltaic encapsulant layer, the solar cell module is a solar cell module which has desired optical properties (such as a high quantum yield) and a good light stability (chemical and physical property) and which restrains the shift or bleeding-out of the fluorescent body. Furthermore, the solar cell module has this encapsulant layer, whereby the luminescent ethylene-based copolymer dispersed in the encapsulant layer does not undergo migration, bleeding-out or any other inconvenience even in a long-term storage test. Thus, the solar cell module is a module excellent in long-term reliability.

It is preferred that the solar cell module of the present invention is configured to cause a light ray radiated into this module to pass through the photovoltaic encapsulant layer before the light ray reaches a solar cell of the module. The configuration makes it possible to convert a broader-range spectrum of solar energy into electricity, with a higher certainty, to heighten the photoelectric conversion efficiency of the module efficiently.

In the solar cell module of the present invention, it is preferred that only as its encapsulant layer positioned at an incident-ray side of the solar cell, the above-defined photovoltaic encapsulant layer is arranged. When a fluorescent body powder is used, a problem is unfavorably caused that the fluorescent body powder migrates inside the encapsulant layer or bleeds out from this layer. Thus, in the case of using a encapsulant composition to which the fluorescent body powder is added, for example, the following countermeasure is beforehand taken, considering the migration inside the layer or between the phases, or bleeding-out outside the layer: the fluorescent body powder is added to both surfaces (i.e., incident-ray side and back sheet side surfaces) of the solar cell; or an attempt is made in which a large amount of the powder is added to the encapsulant layer. However, the countermeasure increases costs for an extra fragment of the fluorescent body powder, and causes a change of the solar cell in performance over time, so that this countermeasure gives a poor long-term reliability. In contrast, the solar cell module of the present invention has the above-mentioned configuration, thereby making it unnecessary to consider beforehand the migration inside the layer or between the phases or the bleeding-out from the layer, and thereby becoming a stable and uniform solar cell module in which fluorescent moieties of its incident-ray-side encapsulant layer are not shifted to, e.g., its encapsulant layer for a solar-cell-backside (rear-surface).

Furthermore, in the solar cell module of the present invention, the solar cell is preferably a crystal silicon solar cell. By using this solar cell module as a solar cell module in which solar cells as described above are stacked onto each other, the photoelectric conversion efficiency thereof can be more effectively made better. In particular, silicon solar cells have a problem of being low in photoelectric conversion efficiency in the range of wavelengths not higher than a maximum absorption wavelength of silicon, which is 400 nm in an ultraviolet wavelength range. In the present solar cell module, an appropriate use of the above-mentioned luminescent ethylene-based copolymer, which has an absorption in this wavelength range and can further emit fluorescence at 400 to 560 nm, makes it possible to use light more effectively. If the absorption wavelength range of the luminescent ethylene-based copolymer is extended into the range of longer wavelengths than the above-mentioned wavelength range, wavelengths which a photoelectric conversion element, such as a solar cell, can originally absorb overlap unfavorably with the absorption wavelengths of the luminescent ethylene-based copolymer, so that the module may fail in being made high in photoelectric conversion efficiency. In the present solar cell module, the use of the above-mentioned luminescent ethylene-based copolymer makes it possible to control the absorption wavelength of the polymeric fluorescent dye compound and others precisely not to cause this problem.

The method of the present invention for producing a luminescent ethylene-based copolymer includes the step of polymerizing a monomer material comprising the above-defined fluorescent dye compound, which has an unsaturated bond, in the presence of a polymerization initiator. This producing method makes it easy to design the molecule of the luminescent ethylene-based copolymer, and makes it possible to yield the luminescent ethylene-based copolymer efficiently.

### BRIEF DESCRIPTION OF THE DRAWINGS

FIG. 1 illustrates an example of a solar cell module in which a encapsulant layer of the present invention for a solar cell is used.

FIG. 2 illustrates an example of the solar cell module, in which the encapsulant layer of the invention for a solar cell is used.

FIG. 3 illustrates an example of the solar cell module, in which the encapsulant layer of the invention for a solar cell is used.

### MODE FOR CARRYING OUT THE INVENTION

Hereinafter, embodiments of the present invention will be described.

### (Fluorescent Compound)

The luminescent ethylene-based copolymer of the present invention includes, as a monomer component, a fluorescent dye compound having an unsaturated bond.

In the luminescent ethylene-based copolymer, the unsaturated bond is preferably a carbon-carbon double bond.

Examples of the carbon-carbon double bond include —CR′═CH₂, —(C═O)O—CR′═CH₂, —O(C═O)—CR′═CH₂, —CH₂O(CO)−CR′═CH₂, —NH(CO)—CR′═CH₂, and —NR—CH₂—CR′═CH₂ wherein R and R's each independently represent an alkyl group having 1 to 8 carbon atoms. When this fluorescent dye compound has this structure, it becomes easy that the fluorescent dye compound forms a chemical bond with a monomer for the ethylene-based copolymer or with the ethylene-based copolymer, particularly, a bond therewith by copolymerization, end-capping or graftage.

More specific examples of the carbon-carbon double bond include ethenyl, propenyl, isopropenyl, butenyl, isobutenyl, pentenyl, hexenyl, heptenyl, 2-ethylhexenyl, octenyl, 3-allyloxy-2-hydroxypropyl, and 3-allyloxy-2-acetoxypropyl. However, the carbon-carbon double bond is not limited to these examples.

It is preferred that the fluorescent dye compound is bonded through a covalent bond to the luminescent ethylene-based copolymer.

In the luminescent ethylene-based copolymer, the fluorescent dye compound preferably has a triazole skeleton such as a benzotriazole skeleton, a carbazole skeleton, a thiadiazole skeleton such as a benzothiadiazole skeleton, a spiropyran skeleton such as a benzotriazolespiropyran skeleton, an acridine skeleton, a xanthene skeleton, an imidazole skeleton such as a benzoimidazole skeleton, an oxazole skeleton such as a benzoxazole skeleton, a quinoxaline skeleton, or a thiazole skeleton such as a benzothiazole skeleton. When the fluorescent dye compound has this structure, the compound easily gives both of long-term reliability and a wavelength-converting function for a encapsulant composition with a good balance.

In the fluorescent dye compound, it would be important for luminescent properties thereof that in an excited state of the compound when the compound absorbs light, an electric-charge separation state inside the molecule thereof is effectively produced. In order to produce the electric-charge separation state inside the molecule in such an excited state, a main skeleton of this compound preferably has a high electron-density atom belonging to the Group 15 and 16, such as nitrogen, oxygen or sulfur. The main skeleton more preferably has two or more high electron-density atoms. These high electron-density atoms are more preferably linked to each other by one or more covalent bonds, or adjacent to each other through one or more carbon atoms by the same bonds.

The fluorescent dye compound is a compound having a function of converting the wavelength of a ray radiated into this compound to a longer wavelength.

The maximum absorption wavelength of the fluorescent dye compound is preferably from 300 to 410 nm. The wavelength may be from 330 to 370 nm, or from 340 to 360 nm.

The maximum fluorescence wavelength of the fluorescent dye compound is preferably from 400 to 560 nm. The wavelength may be from 405 to 490 nm, or from 410 to 470 nm.

The fluorescent dye compound is preferably a compound which absorbs light rays having wavelengths of 340 to 410 nm more largely than light rays having wavelengths more than 410 nm. This is because in a case where the compound absorbs light rays having wavelengths more than 410 nm more largely even when the compound absorbs light rays having wavelengths of 410 nm or less, the total light quantity usable in the photoelectrically converting layer is unfavorably decreased. When the compound absorbs light rays having wavelengths of 340 to 410 nm more largely than light rays having wavelengths more than 410 nm, light rays the wavelengths of which have been converted also come to be usable without decreasing the light rays (direct light rays) usable in the photoelectrically converting layer. As a result, the total light quantity usable in the photoelectrically converting layer can be increased.

The absorbance of the fluorescent dye compound is, for example, preferably from 0.5 to 6, more preferably from 0.8 to 4, even more preferably from 1 to 3. If the absorbance is low, the wavelength-converting function is not easily expressed. If the absorbance is too large, a disadvantage is produced for costs. The absorbance is a value calculated out in accordance with the Lambert-Beer law.

The refractive index of the fluorescent dye compound is, for example, from 1.4 to 1.7, from 1.45 to 1.65, or from 1.45 to 1.55. In some embodiments, the refractive index of the fluorescent dye compound is 1.5.

### (Luminescent Ethylene-Based Copolymer)

The luminescent ethylene-based copolymer of the present invention includes, as a monomer component, the above-defined fluorescent dye compound.

A method for bonding the fluorescent dye compound having an unsaturated bond to the luminescent ethylene-based copolymer (the method: fixation) may be, for example, a method of polymerizing, partially or wholly, the fluorescent dye compound together with a monomer component for producing the luminescent ethylene-based copolymer (copolymerization reaction method); or a method of forming covalent bonds appropriately onto an already-produced or partially-produced ethylene-based copolymer to introduce the fluorescent dye compound to the copolymer (addition-manner introduction method). The monomer component may be a counter pair in end-capping or graftage in the addition-manner introduction method. In any one of these methods, the fixation is preferably attained by bond-formation using mainly a carbon-carbon double bond moiety of the fluorescent dye compound.

When the copolymerization reaction is conducted, a known polymer-synthesizing method is appropriately usable. The method is, for example, a method of subjecting the fluorescent dye compound in the present invention, and a different monomer to random-, graft-, cross-, or block-copolymerization. The copolymerization reaction makes use of, e.g., radical polymerization (cation, anion, each living, and others), ion polymerization, addition polymerization (polyaddition), condensation polymerization (polycondensation), cyclization polymerization, or ring-opening polymerization. The copolymerization reaction appropriately makes use of a synthesis manner, for example, in an organic solvent system or aqueous solution system, or in an emulsion state or suspension state.

Examples of the different monomer include acrylic acid, methacrylic acid, methyl acrylate, methyl methacrylate, ethyl acrylate, ethyl methacrylate, butyl acrylate, butyl methacrylate, 2-ethylhexyl acrylate, 2-ethylhexyl methacrylate, any other alkyl (meth)acrylate, cyclohexyl acrylate, cyclohexyl methacrylate, phenyl acrylate, phenyl methacrylate, benzyl acrylate, benzyl methacrylate, styrene, α-methylstyrene, vinyltoluene, acrylamide, diacetoneacrylamide, acrylonitrile, methacrylonitrile, maleic anhydride, phenylmaleimide, and cyclohexylmaleimide. Other examples thereof include any alkyl (meth)acrylate in which the alkyl group is substituted with, e.g., a hydroxyl group, an epoxy group, or a halogen radical. Additional examples thereof include vinyl acetate, and α-olefin monomers such as 1-hexene and 1-octene. About the alkyl (meth)acrylate, the number of carbon atoms of the alkyl group of the ester moiety therein is preferably from 1 to 18, more preferably from 1 to 8 carbon atoms. In many cases, the raw material for the copolymerization includes, in particular, vinyl acetate or an α-olefin as a monomer component. These compounds may be used singly, or in the form of a mixture of two or more thereof.

At the time of conducting the copolymerization reaction, in the luminescent ethylene-based copolymer, the fluorescent dye compound is used preferably in a copolymeric composition of 0.01 to 20% by weight, and may be used in a copolymeric composition of 0.02 to 15 parts by weight, of 0.05 to 10 parts by weight, of 0.08 to 6 parts by weight, or of 0.1 to 4 parts by weight. When the composition is set into any one of these ranges, the wavelength-converting function of the copolymer can be made compatible, in a well-balanced manner, with the endurance thereof after the copolymer is shaped, or is worked and shaped.

About the luminescent ethylene-based copolymer, the number-average molecular weight of the copolymer can be from 3×10³ to 3×10⁶, and may be from 1×10⁴ to 1×10⁶, from 2×10⁴ to 5×10⁵, or from 4×10⁴ to 2×10⁵. The number-average molecular weight is based on a value measured by GPC (in terms of that of polystyrene). When the number-average molecular weight is set into any one of these ranges, the copolymer is easily shaped or worked, and the endurance thereof may be made more reliable after the copolymer is shaped.

About the luminescent ethylene-based copolymer, the weight-average molecular weight of the copolymer can be from 1×10⁴ to 9×10⁶, and may be from 2×10⁴ to 2×10⁶, from 5×10⁴ to 1×10⁶, or from 1×10⁵ to 8×10⁵. The weight-average molecular weight is based on a value measured by GPC (in terms of that of polystyrene). When the weight-average molecular weight is set into any one of these ranges, the copolymer is easily shaped or worked, and the endurance thereof may be made more reliable after the copolymer is shaped.

About the luminescent ethylene-based copolymer, the melting temperature (Tm) of this copolymer is preferably from 50 to 130° C., and may be from 55 to 120° C., from 60 to 110° C. or from 65 to 100° C. The melting temperature (Tm) (° C.) is rendered a value measured with a differential calorimeter (DSC). When the melting point is set into any one of these ranges, the copolymer is easily shaped or worked, and the endurance thereof may be made more reliable after the copolymer is shaped.

At the time of conducting the copolymerization reaction, the polymerization can be attained, for example, by adding a thermopolymerization initiator or photopolymerization initiator to the monomer components, and then heating the resultant or radiating light to the resultant.

The thermopolymerization initiator may be an appropriate known peroxide. Examples of the polymerization initiator include 2,5-dimethylhexane-2,5-dihydroperoxide, 2,5-dimethyl-2,5-di(t-butylperoxy)hexane-3, di-t-butylperoxide, dicumylperoxide, 2,5-dimethyl-2,5-di(t-butylperoxy)hexane, dicumylperoxide, α,α′-bis(t-butylperoxyisopropyl)benzene, n-butyl-4,4-bis(t-butylperoxy)butane, 2,2-bis(t-butylperoxy)butane, 1,1-bis(t-butylperoxy)cyclohexane, 1,1-bis(t-butylperoxy)3,3,5-trimethylcyclohexane, t-butyl peroxybenzoate, and benzoylperoxide. These compounds may be used singly, or in the form of a mixture of two or more thereof.

The blend amount of the thermopolymerization initiator may be, for example, in an amount of 0.1 to 5 parts by weight for 100 parts by weight of the monomer components.

The above-mentioned photopolymerization initiator may be an appropriate known photopolymerization initiator that produces free radicals by ultraviolet rays or visible rays. Examples of the photopolymerization initiator include benzoin ethers such as benzoin methyl ether, benzoin ethyl ether, benzoin propyl ether, benzoin isobutyl ether, and benzoin phenyl ether; benzophenones such as benzophenone, N,N′-tetramethyl-4,4′-diaminobenzophenone (Michler's ketone), and N,N′-tetraethyl-4,4′-diaminobenzophenone; benzyl ketals such as benzyl dimethyl ketal (IRGACURE 651, manufactured by Ciba Japan K.K.), and benzyl diethyl ketal; acetophenones such as 2,2-dimethoxy-2-phenylacetophenone, p-tert-butyldichloroacetophenone, and p-dimethylaminoacetophenone; xanthones such as 2,4-dimethylthioxanthone, and 2,4-diisopropylthioxanthone; and hydroxycyclohexyl phenyl ketone (IRGACURE 184, manufactured by Ciba Specialty Chemicals, Inc.), 1-(4-isopropylphenyl)-2-hydroxy-2-methylpropane-1-one (DAROCURE 1116, manufactured by Ciba Japan K.K.), and 2-hydroxy-2-methyl-1-phenylpropane-1-one (DAROCURE 1173, manufactured by Merck & Co., Inc.). These initiators may be used singly, or in the form of a mixture of two or more thereof.

The photopolymerization initiator may be, for example, a combination of a 2,4,5-triallylimidazole dimer with 2-mercaptobenzoxazole, leuco crystal violet, or tris(4-diethylamino-2-methylphenyl)methane. A known additive, for example, a tertiary amine such as triethanolamine for benzophenone may be appropriately used.

The blend amount of the photopolymerization initiator may be, for example, from 0.1 to 5 parts by weight for 100 parts by weight of the monomer components.

When the above-mentioned addition-manner introduction method is conducted, a known organic synthesis method is appropriately usable. The method is, for example, a method of subjecting the fluorescent dye compound in the present invention, which has an unsaturated bond, to, e.g., a condensation reaction, addition reaction or substitution reaction to form covalent bonds. Furthermore, the method may be, for example, a method of introducing the fluorescent dye compound into an already produced polymer (or oligomer) to produce the form of the so-called pendant to a main chain skeleton of the polymer; or a method of introducing the fluorescent dye compound into, e.g., a terminal of the main chain skeleton of the polymer to produce the form of an endcap onto the terminal.

In the addition-manner introduction method, the fluorescent dye compound is preferably bonded through a covalent bond to the fluorescent dye compound.

In the addition-manner introduction method, as the polymer having the already-formed polymer structure, an optically transparent ethylene-based copolymer is preferably used. Examples of the ethylene-based copolymer include ethylene-based copolymers each including vinyl acetate or an α-olefin; and polyethylene terephthalate, poly(meth)acrylate, polyvinyl acetate, and polyethylene tetrafluoroethylene. In the ethylene-based copolymer, a further different component may be fittingly copolymerized therewith. These ethylene-based copolymers may be used singly or in the form of a mixture of two or more thereof.

Examples of the above-mentioned resin poly(meth)acrylate include polyacrylate and polymethacrylate, an example of which is a (meth)acrylate resin. Examples of the polyolefin resin include polyethylene, polypropylene, and polybutadiene. Examples of the polyvinyl acetate include polyvinyl formal, polyvinyl butyral (PVB resin), and modified PVB.

Examples of a constituent monomer for the (meth)acrylate resin described just above include alkyl (meth)acrylates such as methyl acrylate, methyl methacrylate, ethyl acrylate, ethyl methacrylate, butyl acrylate, butyl methacrylate, 2-ethylhexyl acrylate, and 2-ethylhexyl methacrylate; and cyclohexyl acrylate, cyclohexyl methacrylate, phenyl acrylate, phenyl methacrylate, benzyl acrylate, and benzyl methacrylate. The constituent monomer may also be any alkyl (meth)acrylate in which any one of the alkyl groups described just above is substituted with, e.g., a hydroxyl group, an epoxy group, or a halogen radical. These compounds may be used singly, or in the form of a mixture of two or more thereof.

In these (meth)acrylates, the number of carbon atoms of the alkyl group in their ester moiety is preferably from 1 to 18, more preferably from 1 to 8.

The above-mentioned (meth)acrylate resin may be rendered a copolymer by using, besides any one of the (meth)acrylates, an unsaturated monomer copolymerizable with the (meth)acrylate.

Examples of the unsaturated monomer include unsaturated organic acids such as methacrylic acid and acrylic acid, styrene, α-methylstyrene, acrylamide, diacetoneacrylamide, acrylonitrile, methacrylonitrile, maleic anhydride, phenylmaleimide, and cyclohexylmaleimide. These unsaturated monomers may be used singly, or in the form of a mixture of two or more thereof.

Out of the (meth)acrylates, particularly preferred are methyl acrylate, ethyl acrylate, isobutyl acrylate, n-butyl acrylate, 2-ethylhexyl acrylate, methyl methacrylate, isobutyl methacrylate, n-butyl methacrylate, and 2-ethylhexyl methacrylate; and any alkyl (meth)acrylate in which the functional group of any one of these (meth)acrylates is substituted. Methyl methacrylate is a more preferred example from the viewpoint of durability and versatility.

The copolymer preferably includes, as one or more monomer components, at least one of α-olefins such as 1-hexene and 1-octene, and vinyl acetate. The copolymer also preferably includes, as monomer components, both of an α-olefin and vinyl acetate. When the copolymer has any one of these structures, the copolymer can have, with a higher certainty, workability, light transmissibility, long-term reliability, and a wavelength-converting function for a encapsulant composition in a well-balanced manner.

The copolymer is, for example, (meth)acrylate-styrene copolymer, or ethylene-vinyl acetate copolymer. Out of these examples, ethylene-vinyl acetate copolymer is preferred from the viewpoint of moisture resistance, versatility, and costs. Moreover, any (meth)acrylate is preferred from the viewpoint of durability and surface hardness. Furthermore, from the above-mentioned individual viewpoints, it is preferred to use ethylene-vinyl acetate copolymer and a (meth)acrylate in combination.

About the ethylene-vinyl acetate copolymer, the content by proportion of the vinyl acetate units is from 10 to 35 parts by weight, more preferably from 20 to 30 parts by weight for 100 parts by weight of the ethylene-vinyl acetate copolymer. Any one of these contents by proportion is preferred from the viewpoint of a uniform dispersibility of, e.g., a rare earth complex into the matrix resin.

When the ethylene-vinyl acetate copolymer or ethylene-α olefin copolymer, or some other is used as the optically transparent ethylene-based copolymer, a commercially available product thereof is fittingly usable. Examples of the commercially available product of the ethylene-vinyl acetate copolymer include ULTRATHENE (manufactured by Tosoh Corp.), EVA FLEX (manufactured by Du Pont-Mitsui Polychemicals Co., Ltd.), SUNTEC EVA (manufactured by Asahi Kasei Chemicals Corp.), UBE EVA copolymer (manufactured by Ube-Maruzen Polyethylene Co., Ltd.), EVATATE (manufactured by Sumitomo Chemical Co., Ltd.), NOVATEC EVA (manufactured by Japan Polyethylene Corp.), SUMITATE (manufactured by Sumitomo Chemical Co., Ltd.), and NIPOFLEX (manufactured by Tosoh Corp.). Examples of the commercially available product of the ethylene-α olefin copolymer include ENGAGE, AFFINITY and INFUSE (each manufactured by the Dow Chemical Co.), TAFMER manufactured by Mitsui Chemicals, Inc., and KERNEL (manufactured by Japan Polyethylene Corp.).

A crosslinking monomer may be added to the luminescent ethylene-based copolymer to render the copolymer a copolymer having a crosslinked structure.

Examples of the crosslinking monomer include dicyclopentenyl (meth)acrylate, tetrahydrofurfuryl (meth)acrylate, benzyl (meth)acrylate, compounds each obtained by causing an α,β-unsaturated carboxylic acid to react with a polyhydric alcohol (for example, polyethylene glycol di(meth)acrylate (the number of ethylene groups: 2 to 14), trimethylolpropane di(meth)acrylate, trimethylolpropane tri(meth)acrylate, trimethylolpropane ethoxytri(meth)acrylate, trimethylolpropane propoxytri(meth)acrylate, tetramethylolmethane tri(meth)acrylate, tetramethylolmethane tetra(meth)acrylate, polypropylene glycol di(meth)acrylate (the number of propylene groups: 2 to 14), dipentaerythritol penta(meth)acrylate, dipentaerythritol hexa(meth)acrylate, bisphenol A polyoxyethylene di(meth)acrylate, bisphenol A dioxyethylene di(meth)acrylate, bisphenol A trioxyethylene di(meth)acrylate, and bisphenol A decaoxyethylene di(meth)acrylate), compounds each obtained by adding an α,β-unsaturated carboxylic acid to a glycidyl-group-containing compound (for example, trimethylolpropane triglycidyl ether triacrylate, and bisphenol A diglycidyl ether diacrylate), esterified products each made from a polybasic carboxylic acid (such as phthalic anhydride) and a substance having a hydroxyl group and an ethylenical unsaturated group (such as β-hydroxyethyl (meth)acrylate), alkyl esters of acrylic acid or methacrylic acid (for example, methyl (meth)acrylate, ethyl (meth)acrylate, butyl (meth)acrylate, and 2-ethylhexyl (meth)acrylate), and urethane (meth)acrylates (for example, a reactant made from tolylene diisocyanate and 2-hydroxyethyl (meth)acrylate, and a reactant made from trimethylhexamethylene diisocyanate, cyclohexanedimethanol, and 2-hydroxyethyl (meth)acrylate). These crosslinking monomers may be used singly, or in the form of a mixture of two or more thereof. Out of these crosslinking monomers, preferred are trimethylolpropane tri(meth)acrylate, dipentaerythritol tetra(meth)acrylate, dipentaerythritol hexa(meth)acrylate, and bisphenol A polyoxyethylene dimethacrylate.

When the matrix resin containing the crosslinking monomer is used, a crosslinked structure can be formed, for example, by adding a thermopolymerization initiator or photopolymerization initiator to the crosslinking monomer, and then heating the resultant or irradiating the resultant with light to be polymerized and crosslinked.

The thermopolymerization initiator may be an appropriate known peroxide. Examples of the thermopolymerization initiator include 2,5-dimethylhexane-2,5-dihydroperoxide, 2,5-dimethyl-2,5-di(t-butylperoxy)hexane-3, di-t-butylperoxide, dicumylperoxide, 2,5-dimethyl-2,5-di(t-butylperoxy)hexane, dicumylperoxide, α,α′-bis(t-butylperoxyisopropyl)benzene, n-butyl-4,4-bis(t-butylperoxy)butane, 2,2-bis(t-butylperoxy)butane, 1,1-bis(t-butylperoxy)cyclohexane, 1,1-bis(t-butylperoxy)3,3,5-trimethylcyclohexane, t-butyl peroxybenzoate, and benzoylperoxide. These compounds may be used singly, or in the form of a mixture of two or more thereof.

The blend amount of the thermopolymerization initiator may be, for example, in an amount of 0.1 to 5 parts by weight for 100 parts by weight of the matrix resin.

The above-mentioned photopolymerization initiator may be an appropriate known photopolymerization initiator that produces free radicals by ultraviolet rays or visible rays. Examples of the photopolymerization initiator include benzoin ethers such as benzoin methyl ether, benzoin ethyl ether, benzoin propyl ether, benzoin isobutyl ether, and benzoin phenyl ether; benzophenones such as benzophenone, N,N′-tetramethyl-4,4′-diaminobenzophenone (Michler's ketone), and N,N′-tetraethyl-4,4′-diaminobenzophenone; benzyl ketals such as benzyl dimethyl ketal (IRGACURE 651, manufactured by Ciba Japan K.K.), and benzyl diethyl ketal; acetophenones such as 2,2-dimethoxy-2-phenylacetophenone, p-tert-butyldichloroacetophenone, and p-dimethylaminoacetophenone; xanthones such as 2,4-dimethylthioxanthone, and 2,4-diisopropylthioxanthone; and hydroxycyclohexyl phenyl ketone (IRGACURE 184, manufactured by Ciba Specialty Chemicals, Inc.), 1-(4-isopropylphenyl)-2-hydroxy-2-methylpropane-1-one (DAROCURE 1116, manufactured by Ciba Japan K.K.), and 2-hydroxy-2-methyl-1-phenylpropane-1-one (DAROCURE 1173, manufactured by Merck & Co., Inc.). These initiators may be used singly, or in the form of a mixture of two or more thereof.

The photopolymerization initiator may be, for example, a combination of a 2,4,5-triallylimidazole dimer with 2-mercaptobenzoxazole, leuco crystal violet, or tris(4-diethylamino-2-methylphenyl)methane. A known additive, for example, a tertiary amine such as triethanolamine for benzophenone may be appropriately used.

The blend amount of the photopolymerization initiator is, for example, from 0.1 to 5 parts by weight for 100 parts by weight of the matrix resin.

The luminescent ethylene-based copolymer is a copolymer having a function of converting the wavelength of a ray radiated into this copolymer to a longer wavelength.

The maximum absorption wavelength of the luminescent ethylene-based copolymer is preferably from 300 to 410 nm. The wavelength may be from 330 to 370 nm, or from 340 to 360 nm.

The maximum fluorescence wavelength of the luminescent ethylene-based copolymer is preferably from 400 to 560 nm. The wavelength may be from 405 to 490 nm, or from 410 to 470 nm.

The absorbance of the luminescent ethylene-based copolymer is, for example, preferably from 0.5 to 6, more preferably from 0.8 to 4, even more preferably from 1 to 3.

The refractive index of the luminescent ethylene-based copolymer ranges, for example, from 1.4 to 1.7, from 1.45 to 1.65 or from 1.45 to 1.55. In some embodiments, the refractive index of the luminescent ethylene-based copolymer is 1.5.

### (Photovoltaic Encapsulant Composition)

The encapsulant composition of the present invention for a solar cell is a composition having a wavelength-converting function (wavelength-converting encapsulant composition). The encapsulant composition is preferably a composition for converting the wavelength of a light ray radiated into the composition to a longer wavelength. The encapsulant composition is preferably optically transparent, and can be produced by incorporating the above-defined luminescent ethylene-based copolymer into other components of this composition. The photovoltaic encapsulant composition may make use of the luminescent ethylene-based copolymer as amain component. Alternatively, in this composition, a different matrix resin may be used together with the copolymer to render the matrix resin a main component.

About the encapsulant composition, only the luminescent ethylene-based copolymer may be used as a matrix material of this composition without using any other different matrix resin.

When the photovoltaic encapsulant composition of the present invention includes the luminescent ethylene-based copolymer, a different matrix resin may be appropriately used in combination with the copolymer. The different matrix resin is preferably an optically transparent resin. Examples of the matrix resin include ethylene-based copolymer including vinyl acetate or an α-olefin, polyethylene terephthalate, poly(meth)acrylate, polyvinyl acetate, any polyolefin such as polyethylene tetrafluoroethylene, polyimide, amorphous polycarbonate, siloxane sol-gel, polyurethane, polystyrene, polyethersulfone, polyarylate, epoxy resin, and silicone resin. These matrix resins may be used singly or in the form of a mixture of two or more thereof. In the case of the above-mentioned combination use, the content by percentage of the fluorescent dye compound in the luminescent ethylene-based copolymer is appropriately adjustable in accordance with the blend ratio between the different matrix resin and the luminescent ethylene-based copolymer to be mixed with each other. The luminescent ethylene-based copolymer used in the case of the combination use is, for example, the luminescent ethylene-based copolymer in which the fluorescent dye compound is copolymerized in a proportion of 1%, 2%, 3%, 5%, 8%, 10%, 15%, 20%, 30%, 40% or 50% by mole. In the photovoltaic encapsulant composition, for example, the following may be used as a main component: the luminescent ethylene-based copolymer including the fluorescent dye compound to an extent necessary for the wavelength-converting function of the above-defined encapsulant layer. For example, about the photovoltaic encapsulant composition, it is allowable to heighten the content by percentage of the fluorescent dye compound in the luminescent ethylene-based copolymer, and use a different matrix resin in combination with the copolymer to render the different matrix resin a main component.

Examples of the above-mentioned resin poly(meth)acrylate include polyacrylate and polymethacrylate, an example of which is a (meth)acrylate resin. Examples of the polyolefin resin include polyethylene, polypropylene, and polybutadiene. Examples of the polyvinyl acetate include polyvinyl formal, polyvinyl butyral (PVB resin), and modified PVB.

Examples of a constituent monomer for the (meth)acrylate resin described just above include alkyl (meth)acrylates such as methyl acrylate, methyl methacrylate, ethyl acrylate, ethyl methacrylate, butyl acrylate, butyl methacrylate, 2-ethylhexyl acrylate, and 2-ethylhexyl methacrylate; and cyclohexyl acrylate, cyclohexyl methacrylate, phenyl acrylate, phenyl methacrylate, benzyl acrylate, and benzyl methacrylate. The constituent monomer may also be any alkyl (meth)acrylate in which any one of the alkyl groups described just above is substituted with, e.g., a hydroxyl group, an epoxy group, or a halogen radical. These compounds may be used singly, or in the form of a mixture of two or more thereof.

In these (meth)acrylates, the number of carbon atoms of the alkyl group in their ester moiety is preferably from 1 to 18, more preferably from 1 to 8.

The above-mentioned (meth)acrylate resin may be rendered a copolymer by using, besides any one of the (meth)acrylates, an unsaturated monomer copolymerizable with the (meth)acrylate.

Examples of the unsaturated monomer include unsaturated organic acids such as methacrylic acid and acrylic acid, styrene, α-methylstyrene, acrylamide, diacetoneacrylamide, acrylonitrile, methacrylonitrile, maleic anhydride, phenylmaleimide, and cyclohexylmaleimide. These unsaturated monomers may be used singly, or in the form of a mixture of two or more thereof.

Out of the (meth)acrylates, particularly preferred are methyl acrylate, ethyl acrylate, isobutyl acrylate, n-butyl acrylate, 2-ethylhexyl acrylate, methyl methacrylate, isobutyl methacrylate, n-butyl methacrylate, and 2-ethylhexyl methacrylate; and any alkyl (meth)acrylate in which the functional group of any one of these (meth)acrylates is substituted. Methyl methacrylate is a more preferred example from the viewpoint of durability and versatility.

The copolymer made from the (meth)acrylate and the unsaturated monomer is, for example, a (meth)acrylate-styrene copolymer, or an ethylene-vinyl acetate copolymer. Out of these examples, an ethylene-vinyl acetate copolymer is preferred from the viewpoint of moisture resistance, versatility, and costs. Moreover, any (meth)acrylate is preferred from the viewpoint of durability and surface hardness. Furthermore, from the above-mentioned individual viewpoints, it is preferred to use an ethylene-vinyl acetate copolymer and a (meth)acrylate in combination.

About the ethylene-vinyl acetate copolymer, the content by proportion of the vinyl acetate units is from 10 to 35 parts by weight, more preferably from 20 to 30 parts by weight for 100 parts by weight of the ethylene-vinyl acetate copolymer. Any one of these contents by proportion is preferred from the viewpoint of a uniform dispersibility of, e.g., a rare earth complex into the matrix resin.

When the ethylene-vinyl acetate copolymer, the ethylene-α olefin, or some other is used as the optically transparent matrix resin, a commercially available product thereof is fittingly usable. Examples of the commercially available product of the ethylene-vinyl acetate copolymer include ULTRACENE (manufactured by Tosoh Corp.), EVAFLEX (manufactured by Du Pont-Mitsui Polychemicals Co., Ltd.), SUNTEC EVA (manufactured by Asahi Kasei Chemicals Corp.), UBE EVA copolymer (manufactured by Ube-Maruzen Polyethylene Co., Ltd.), EVATATE (manufactured by Sumitomo Chemical Co., Ltd.), NOVATEC EVA (manufactured by Japan Polyethylene Corp.), SUMITATE (manufactured by Sumitomo Chemical Co., Ltd.), and NIPOFLEX (manufactured by Tosoh Corp.). Examples of the commercially available product of the ethylene-α olefin copolymer include ENGAGE, AFFINITY and INFUSE (each manufactured by the Dow Chemical Co.), TAFMER manufactured by Mitsui Chemicals, Inc., and KERNEL (manufactured by Japan Polyethylene Corp.).

A crosslinking monomer may be added to the matrix resin to render the resin a resin having a crosslinked structure.

Examples of the crosslinking monomer include dicyclopentenyl (meth)acrylate, tetrahydrofurfuryl (meth)acrylate, benzyl (meth)acrylate, compounds each obtained by causing an α,β-unsaturated carboxylic acid to react with a polyhydric alcohol (for example, polyethylene glycol di(meth)acrylate (the number of ethylene groups: 2 to 14), trimethylolpropane di(meth)acrylate, trimethylolpropane tri(meth)acrylate, trimethylolpropane ethoxytri(meth)acrylate, trimethylolpropane propoxytri(meth)acrylate, tetramethylolmethane tri(meth)acrylate, tetramethylolmethane tetra(meth)acrylate, polypropylene glycol di(meth)acrylate (the number of propylene groups: 2 to 14), dipentaerythritol penta(meth)acrylate, dipentaerythritol hexa(meth)acrylate, bisphenol A polyoxyethylene di(meth)acrylate, bisphenol A dioxyethylene di(meth)acrylate, bisphenol A trioxyethylene di(meth)acrylate, and bisphenol A decaoxyethylene di(meth)acrylate), compounds each obtained by adding an α,β-unsaturated carboxylic acid to a glycidyl-group-containing compound (for example, trimethylolpropane triglycidyl ether triacrylate, and bisphenol A diglycidyl ether diacrylate), esterified products each made from a polybasic carboxylic acid (such as phthalic anhydride) and a substance having a hydroxyl group and an ethylenical unsaturated group (such as β-hydroxyethyl (meth)acrylate), alkyl esters of acrylic acid or methacrylic acid (for example, methyl (meth)acrylate, ethyl (meth)acrylate, butyl (meth)acrylate, and 2-ethylhexyl (meth)acrylate), and urethane (meth)acrylates (for example, a reactant made from tolylene diisocyanate and 2-hydroxyethyl (meth)acrylate, and a reactant made from trimethylhexamethylene diisocyanate, cyclohexanedimethanol, and 2-hydroxyethyl (meth)acrylate). These crosslinking monomers may be used singly, or in the form of a mixture of two or more thereof. Out of these crosslinking monomers, preferred are trimethylolpropane tri(meth)acrylate, dipentaerythritol tetra(meth)acrylate, dipentaerythritol hexa(meth)acrylate, and bisphenol A polyoxyethylene dimethacrylate.

When the matrix resin containing the crosslinking resin is used, a crosslinked structure can be formed, for example, by adding a thermopolymerization initiator or photopolymerization initiator to the crosslinking monomer, and then heating the resultant or irradiating the resultant with light to be polymerized and crosslinked.

The thermopolymerization initiator may be an appropriate known peroxide. Examples of the thermopolymerization initiator include 2,5-dimethylhexane-2,5-dihydroperoxide, 2,5-dimethyl-2,5-di(t-butylperoxy)hexane-3, di-t-butylperoxide, dicumylperoxide, 2,5-dimethyl-2,5-di(t-butylperoxy)hexane, dicumylperoxide, α,α′-bis(t-butylperoxyisopropyl)benzene, n-butyl-4,4-bis(t-butylperoxy)butane, 2,2-bis(t-butylperoxy)butane, 1,1-bis(t-butylperoxy)cyclohexane, 1,1-bis(t-butylperoxy)3,3,5-trimethylcyclohexane, t-butyl peroxybenzoate, and benzoylperoxide. These compounds may be used singly, or in the form of a mixture of two or more thereof.

The blend amount of the thermopolymerization initiator may be, for example, in an amount of 0.1 to 5 parts by weight for 100 parts by weight of the total of the luminescent ethylene-based copolymer and, if used, the matrix resin.

The above-mentioned photopolymerization initiator may be an appropriate known photopolymerization initiator that produces free radicals by ultraviolet rays or visible rays. Examples of the photopolymerization initiator include benzoin ethers such as benzoin methyl ether, benzoin ethyl ether, benzoin isopropyl ether, benzoin isobutyl ether, and benzoin phenyl ether; benzophenones such as benzophenone, N,N′-tetramethyl-4,4′-diaminobenzophenone (Michler's ketone), and N,N′-tetraethyl-4,4′-diaminobenzophenone; benzyl ketals such as benzyl dimethyl ketal (IRGACURE 651, manufactured by Ciba Japan K.K.), and benzyl diethyl ketal; acetophenones such as 2,2-dimethoxy-2-phenylacetophenone, p-tert-butyldichloroacetophenone, and p-dimethylaminoacetophenone; xanthones such as 2,4-dimethylthioxanthone, and 2,4-diisopropylthioxanthone; and hydroxycyclohexyl phenyl ketone (IRGACURE 184, manufactured by Ciba Specialty Chemicals, Inc.), 1-(4-isopropylphenyl)-2-hydroxy-2-methylpropane-1-one (DAROCURE 1116, manufactured by Ciba Japan K.K.), and 2-hydroxy-2-methyl-1-phenylpropane-1-one (DAROCURE 1173, manufactured by Merck & Co., Inc.). These initiators may be used singly, or in the form of a mixture of two or more thereof.

The photopolymerization initiator may be, for example, a combination of a 2,4,5-triallylimidazole dimer with 2-mercaptobenzoxazole, leuco crystal violet, or tris(4-diethylamino-2-methylphenyl)methane. A known additive, for example, a tertiary amine such as triethanolamine for benzophenone may be appropriately used.

The blend amount of the photopolymerization initiator is, for example, from 0.1 to 5 parts by weight for 100 parts by weight of the total of the luminescent ethylene-based copolymer and, if used, the matrix resin.

The encapsulant composition can be produced, for example, by mixing or dispersing the above-defined luminescent ethylene-based copolymer and the above-defined matrix resin with each other. For this method, for example, a manner may be used in which these components are melted and kneaded, or mixed with each other in a solution, and thereafter (or after the resultant is further cast) a solvent therein is removed. Only the luminescent ethylene-based copolymer may be used as a material for the matrix.

The encapsulant composition of the present invention includes the above-defined luminescent ethylene-based copolymer. In the above-defined photovoltaic encapsulant composition, the luminescent ethylene-based copolymer may be used as a main component, or a different matrix resin may be used together with the copolymer to render the resin a main component. For example, in the former case, where the luminescent ethylene-based copolymer is used as a main component, the luminescent ethylene-based copolymer may be contained in a proportion of 50 to 100% by weight. The proportion may be in the range of 55 to 95% by weight, of 60 to 90% by weight, of 75 to 85% by weight, or of 70 to 80% by weight. In the latter case, where a different matrix resin is used together with the copolymer to render the resin a main component, the luminescent ethylene-based copolymer may be contained, for example, in a proportion of 0.01 to 49.9% by weight. The proportion may be in the range of 0.1 to 45% by weight, of 1 to 40% by weight, of 2 to 35% by weight, of 3 to 30% by weight, of 5 to 25% by weight, of 8 to 20% by weight, or of 10 to 15% by weight.

The maximum absorption wavelength of the encapsulant composition is preferably from 300 to 410 nm. The wavelength may be from 330 to 370 nm, or from 340 to 360 nm.

The maximum fluorescence wavelength of the encapsulant composition is preferably from 400 to 560 nm. The wavelength may be from 405 to 490 nm, or from 410 to 470 nm.

The absorbance of the encapsulant composition is, for example, preferably from 0.5 to 6, more preferably from 0.8 to 4, even more preferably from 1 to 3.

The refractive index of the encapsulant composition ranges, for example, from 1.4 to 1.7, from 1.45 to 1.65 or from 1.45 to 1.55. In some embodiments, the refractive index of the encapsulant composition is 1.5.

The encapsulant composition may appropriately contain a known additive as far as a desired performance thereof is not damaged. Examples of the additive include a thermoplastic polymer, an antioxidant, an ultraviolet preventing agent, a light stabilizer, an organic peroxide, a filler, a plasticizer, a silane coupling agent, an acid receiving agent, and clay. These may be used singly or in the form of a mixture of two or more thereof.

In order to produce the encapsulant composition, it is sufficient to perform the production in accordance with a known method. The method is, for example, a method of heating and kneading the above-mentioned individual materials to be mixed with each other in a known manner, using, e.g., a super mixer (high-velocity flowing mixer), a roll mill, or a Plastomill. The production may be performed continuously to the production of the above-defined encapsulant layer.

### (Wavelength-converting Encapsulant Layer)

The encapsulant layer of the present invention for a solar cell is a layer formed using the above-defined photovoltaic encapsulant composition. The encapsulant layer is a layer having a wavelength-converting function (wavelength-converting encapsulant layer).

In order to produce the encapsulant layer, it is sufficient to perform the production in accordance with a known method. This layer can be appropriately produced by, for example, a method of heating and kneading the above-mentioned individual materials to be mixed with each other in a known manner, using, e.g., a super mixer (high-velocity flowing mixer), a roll mill or a Plastomill, and then shaping the resultant composition into a sheet product by, e.g., an ordinary extrusion, calendering, or vacuum hot press. Moreover, this layer can be produced by forming the same layer as described just above onto, e.g., a PET film, and then transferring this layer onto a surface protective layer. Furthermore, a method is usable in which a hot melt applicator is used to knead and melt the composition simultaneously with the application of the composition.

More specifically, for example, the above-defined encapsulant composition, which contains the above-defined luminescent ethylene-based copolymer, may be applied, as it is, onto, e.g., a surface protective layer or a separator, or this material may be applied in the state of being mixed with a different material to be made into a mixed composition. The encapsulant composition may be formed by, e.g., vapor deposition, sputtering or an aerosol deposition method.

In the case of the application of the mixed composition, the melting point of the encapsulant composition is preferably from 50 to 250° C., more preferably from 50 to 200° C., even more preferably from 50 to 180° C., considering the workability of the composition. When the melting point of the encapsulant composition is, for example, from 50 to 250° C., the kneading and melting temperature of the composition, and the application temperature thereof are each preferably a temperature of the melting point plus a temperature of 30 to 100° C.

In some embodiments, the encapsulant layer is produced into a thin film structure through the following steps: step (i) of preparing a polymer solution in which powder of the above-defined luminescent ethylene-based copolymer (and the above-defined different matrix resin) is dissolved in a solvent (such as tetrachloroethylene (TCE), cyclopentanone, or dioxane) to give a predetermined proportion; step (ii) of forming a polymer thin film by causing the polymer solution to flow directly onto a glass substrate, subsequently treating the substrate thermally at temperatures from room temperature to at highest 100° C. over 2 hours, and then heating the resultant in a vacuum at 130° C. all night to remove a remaining fragment of the solvent; step (iii) of peeling off the polymer thin film in water and then drying the resultant self-standing type polymer film completely before the thin film structure is used; and step (iv) of being able to control the thickness of the film by changing the concentration in the polymer solution, and the evaporation velocity thereof.

The thickness of the encapsulant layer is preferably from 20 to 2000 μm, more preferably from 50 to 1000 μm, even more preferably from 100 to 800 μm. If the thickness is smaller than 5 μm, this layer does not easily express a wavelength-converting function. In the meantime, if the thickness is larger than 700 μm, this layer is disadvantageous for costs. The use of the encapsulant layer makes it possible to prevent the dye compound from bleeding out, or decrease the bleeding-out largely even when the encapsulant layer is rendered, for example, a thin layer of 600 μm thickness, the bleeding-out being observed merely when a dye compound is added to the encapsulant layer.

The maximum absorption wavelength of the encapsulant layer is preferably from 300 to 410 nm. The wavelength may be from 330 to 370 nm, or from 340 to 360 nm.

The maximum fluorescence wavelength of the encapsulant layer is preferably from 400 to 560 nm. The wavelength may be from 405 to 490 nm, or from 410 to 470 nm.

The absorbance of the encapsulant layer is preferably from 0.5 to 6, more preferably from 0.8 to 4, even more preferably from 1 to 3.

The refractive index of the encapsulant layer is, for example, from 1.4 to 1.7, from 1.45 to 1.65, or from 1.45 to 1.55. In some embodiments, the refractive index of the encapsulant layer is 1.5.

### (Solar Cell Module)

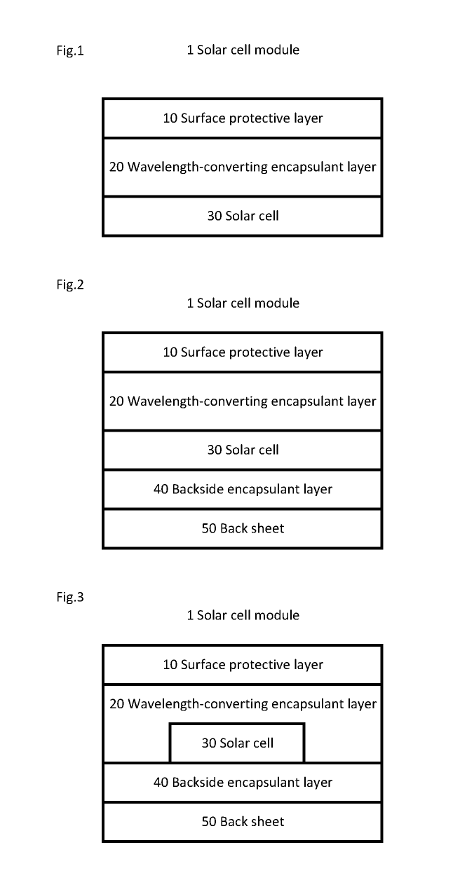

A solar cell module 1 of the present invention includes a surface protective layer 10, a layer 20 for a solar cell that is the above-defined encapsulant layer, and a solar cell 30. A simple schematic view thereof is illustrated, as an example, in each of FIGS. 1 to 3. However, the present invention is not limited to these examples. As illustrated in each of FIGS. 2 and 3, the solar cell may further have, on the backside surface thereof, another encapsulant layer 40, and a back sheet 50 appropriately. As far as the function of the photovoltaic encapsulant layer is not damaged, between any two of these layers a different layer such as an adhesive layer or a pressure-sensitive adhesive layer may fittingly be interposed. The encapsulant layer for the backside surface may be a photovoltaic encapsulant layer (wavelength-converting encapsulant layer) of the present invention as the case may be.

The solar cell module has the above-defined wavelength-converting encapsulant layer to make it possible to convert wavelengths which do not usually contribute to photoelectric conversion to wavelengths which can contribute to photoelectric conversion. Specifically, a certain wavelength can be converted to a longer wavelength. For example, wavelengths shorter than 380 nm can be converted to wavelengths of 380 nm and more. The solar cell module is a module for converting, in particular, ultraviolet ray wavelengths (of 200 to 365 nm) to visible ray wavelengths (of 400 to 800 nm). This range of wavelengths contributing to photoelectric conversion is varied in accordance with the species of the solar cell. Even when this solar cell is, for example, a silicon solar cell, the range is varied in accordance with the crystal form of the used silicon. In the case of, for example, an amorphous silicon solar cell and a polycrystal silicon solar cell, the respective photoelectric-conversion-contributing wavelength ranges thereof would be from 400 to 700 nm, and from about 600 to 1100 nm. Thus, wavelengths contributing to photoelectric conversion are not necessarily limited to visible ray wavelengths. Furthermore, since the solar cell module of the present invention has the encapsulant layer, the fluorescent dye compound does not precipitate even in a long-term storage test of the module, such a precipitation being generatable when a fluorescent dye powder is added to a matrix resin. Consequently, the fluorescent dye compound can be restrained from being shifted to the backside-surface encapsulant layer 40, to the outside of the wavelength-converting encapsulant layer 20 or the module 1, or to some other member. Thus, the solar cell module is a stable and uniform solar cell module.

The above-mentioned solar cell may be, for example, a cadmium-sulfide/cadmium-telluride solar cell, a copper indium gallium biselenide solar cell, amorphous or microcrystalline silicon solar cell, or a crystal silicon solar cell. More specifically, the solar cell can be applied to a silicon solar cell, using, e.g., an amorphous silicon or polycrystal silicon, a compound semiconductor solar cell using, e.g., GaAs, CIS or CIGS, or an organic solar cell such as an organic thin film solar cell, a dye-sensitized solar cell or a quantum dot solar cell. In any one of these solar cells, according to an ordinary use thereof, ultraviolet ray wavelengths do not easily contribute to photoelectric conversion. The solar cell is preferably a crystal silicon solar cell.

In the production of the solar cell module, the above-defined encapsulant layer for a solar cell may be transferred onto the solar cell or the like, or may be applied and formed directly onto the solar cell. The photovoltaic encapsulant layer and any other layer may be simultaneously formed.

The solar cell module of the present invention is preferably configured in such a manner that rays radiated into the module passes through the encapsulant layer before the rays reach the solar cell. The configuration makes it possible to convert a broader-range spectrum of solar energy into electricity, with a higher certainty, to heighten the photoelectric conversion efficiency of the module efficiently.

In the solar cell module of the present invention, it is preferred that only as its encapsulant layer positioned at an incident-ray side of its solar cell, the above-defined wavelength-converting encapsulant layer is arranged. When a fluorescent body powder is used, a problem is unfavorably caused that the fluorescent body powder migrates inside the encapsulant layer or bleeds out from this layer. Thus, in the case of using a encapsulant composition to which the fluorescent body powder is added, for example, the following countermeasure is taken, considering the migration inside the layer or between the phases, or bleeding-out from the layer beforehand: the fluorescent body powder is added to both surfaces (i.e., incident-ray side and back sheet side surfaces) of the solar cell; or an attempt is made in which a large amount of the powder is added to the encapsulant layer. In, e.g., each of FIGS. 2 and 3, in the case of adding a fluorescent body powder to the wavelength-converting encapsulant layer 20, the following countermeasure unfavorably becomes necessary, considering the shift of the powder over time from the wavelength-converting encapsulant layer 20 to the outside of the module 1 or to the backside encapsulant layer 40: a countermeasure in which a large amount of the fluorescent body powder is beforehand added to the wavelength-converting encapsulant layer 20; or a countermeasure in which the fluorescent body is added also to the backside encapsulant layer 40, for which a wavelength-converting function is not required, to adjust substantially the shift/equilibrium of the fluorescent body between the wavelength-converting encapsulant layer 20 and the backside encapsulant layer 40. However, the countermeasure increases costs for an extra fragment of the fluorescent body powder, and causes a change of the solar cell module in performance over time, so that this countermeasure gives a poor long-term reliability. In contrast, in the solar cell module of the present invention, the above-defined photovoltaic encapsulant layer can be arranged only as the encapsulant layer positioned at the incident-ray side of the solar cell (the wavelength-converting encapsulant layer 20 in each of FIGS. 2 and 3). Thus, without considering beforehand the migration inside the layer or between the phases or the bleeding-out from the layer, the present invention provides a stable and uniform solar cell module in which fluorescent moieties of an incident-ray-side encapsulant layer are not shifted to, e.g., a backside encapsulant layer and thus the necessary amount of the fluorescent body is restrained.

The above-mentioned surface protective layer 10 may be a known layer usable as a surface protective layer for a solar cell. The surface protective layer may be, for example, a front sheet, or a glass piece. As the glass piece, various glass pieces may be fittingly used, examples thereof including a white glass plate, or a glass piece with or without embossment.

The backside encapsulant layer 40 and the back sheet 50 may each be a known layer or sheet used as a surface protective layer for solar cells.

### EXAMPLES

Hereinafter, a description will be made about working examples thereof that specifically demonstrate the structure and the advantageous effects of the present invention, and others.

### Example 1

Into an autoclave (volume: 1 L) having electromagnetic upper and lower stirrers were charged 10 parts by weight of vinyl acetate, 100 parts by weight of t-butyl alcohol, 0.2 part by weight of AIBN, and 2 parts by weight of a fluorescent dye compound (compound (1)) having covalent unsaturated bonds. Nitrogen gas was blown into the mixed solution for about 5 minutes to remove air dissolved therein. A lid of the autoclave was then closed. Furthermore, nitrogen gas was blown into the autoclave. In such a way, at a pressure of about 30 kg/cm², the gas in the autoclave was substituted five times. Substantially the same operation was made, using ethylene gas. Thereafter, while the stirrers were worked, the autoclave started to be heated. When the inside temperature thereof reached 65° C., from a cylinder, ethylene gas was put into the autoclave under pressure to give an ethylene pressure of 70 kg/cm². Thereafter, at a reaction temperature of 65° C., the components in the autoclave were stirred for 6 hours, and then the autoclave was cooled to room temperature to stop the reaction. An unreacted fragment of ethylene was then released. The resultant reactant was re-precipitated in an acetone-water system to be produced. This process gave an ethylene:vinyl acetate (ratio by mole: 9:1) copolymer in which approximately 1% by mole of the fluorescent dye compound (1) was polymerized (yield amount: 21 parts by weight; yield percentage: 70% in terms of the amount of vinyl acetate). The resultant copolymer had a number-average molecular weight of 3.5×10⁴, a weight-average molecular weight of 1.2×10⁵, and a melting temperature of 70° C.

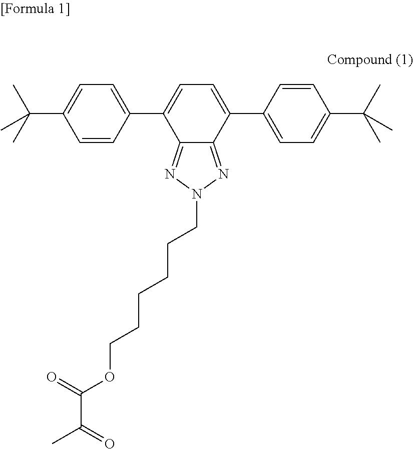 [SMILES: CC(=O)C(=O)OCCCCCCn1nc2c(-c3ccc(C(C)(C)C)cc3)ccc(-c3ccc(C(C)(C)C)cc3)c2n1]

Into 100 parts by weight of the resultant luminescent copolymer were blended 1 part by weight of a crosslinking agent (2,5-dimethyl-2,5-di(t-butylperoxy)hexane), 0.3 part by weight of a silane coupling agent (γ-methacryloxypropyltrimethoxysilane), and 1 part by weight of a crosslinking aid (triallylisocyanate). The resultant was kneaded at 80° C., and then a hot press machine was used to make the kneaded material into a sheet at 80° C. In this way, a photovoltaic encapsulant sheet was yielded.

### Examples 2 to 12

The same manner as in Example 1 was performed to produce photovoltaic encapsulant sheets in which compounds (2) to (12) were used, respectively, instead of the compound (1).

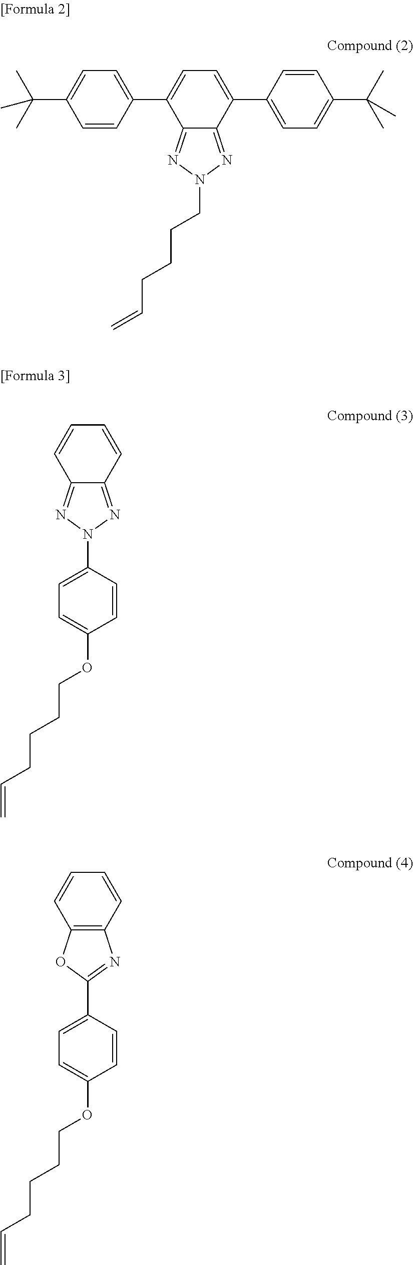 [SMILES: C=CCCCCn1nc2c(-c3ccc(C(C)(C)C)cc3)ccc(-c3ccc(C(C)(C)C)cc3)c2n1 ; C=CCCCCOc1ccc(-n2nc3ccccc3n2)cc1 ; C=CCCCCOc1ccc(-c2nc3ccccc3o2)cc1]

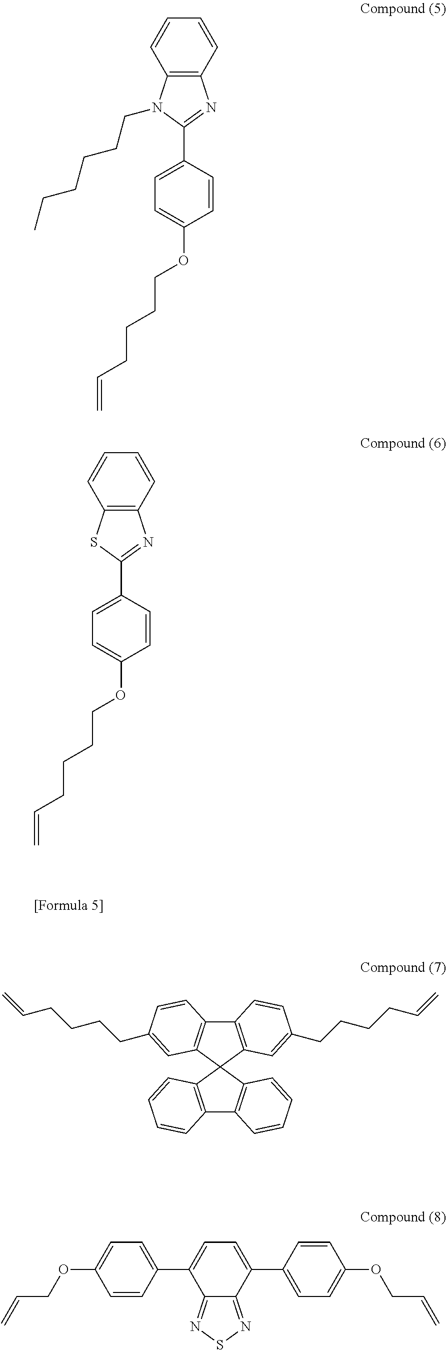

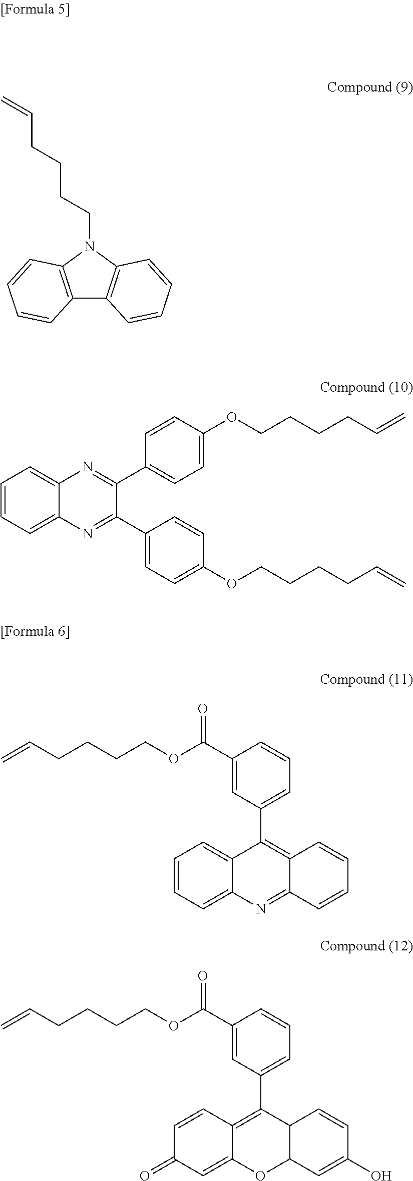

### Comparative Example 1

Into 100 parts by weight of a commercially available EVA resin (ULTRACENE, manufactured by Toli Corporation) were blended 1 part by weight of a crosslinking agent (2,5-dimethyl-2,5-di(t-butylperoxy)hexane), 0.3 part by weight of a silane coupling agent (γ-methacryloxypropyltrimethoxysilane), 1 part by weight of a crosslinking aid (triallylisocyanate), and 1 part by weight of a fluorescent dye compound (compound (13)) having no unsaturated bond. The resultant was kneaded at 80° C., and then a hot press machine was used to make the kneaded material into a sheet at 80° C. In this way, a photovoltaic encapsulant sheet was yielded.

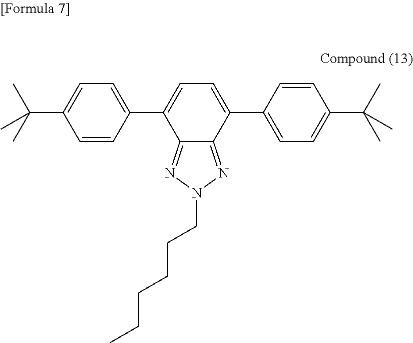 [SMILES: CCCCCCn1nc2c(-c3ccc(C(C)(C)C)cc3)ccc(-c3ccc(C(C)(C)C)cc3)c2n1]

### Example 13

Into an autoclave (volume: 1 L) having electromagnetic upper and lower stirrers were charged 10 parts by weight of vinyl acetate, 100 parts by weight of t-butyl alcohol, 0.2 part by weight of AIBN, and 20 parts by weight of a fluorescent dye compound (compound (1)) having covalent unsaturated bonds. Nitrogen gas was blown into the mixed solution for about 5 minutes to remove air dissolved therein. A lid of the autoclave was then closed. Furthermore, nitrogen gas was blown into the autoclave. In such a way, at a pressure of about 30 kg/cm², the gas in the autoclave was substituted five times. Substantially the same operation was made, using ethylene gas. Thereafter, while the stirrers were worked, the autoclave started to be heated. When the inside temperature thereof reached 65° C., from a cylinder, ethylene gas was put into the autoclave under pressure to give an ethylene pressure of 70 kg/cm². Thereafter, at a reaction temperature of 65° C., the components in the autoclave were stirred for 6 hours, and then the autoclave was cooled to room temperature to stop the reaction. An unreacted fragment of ethylene was then released. The resultant reactant was re-precipitated in an acetone-water system to be produced. This process gave an ethylene:vinyl acetate (ratio by mole: 8:1) copolymer in which approximately 9% by mole of the fluorescent dye compound (1) was polymerized (yield amount: 19 parts by weight; yield percentage: 68% in terms of the amount of vinyl acetate). The resultant copolymer had a number-average molecular weight of 2.9×10⁴, a weight-average molecular weight of 1.3×10⁵, and a melting temperature of 72° C.

Into 10 parts by weight of the resultant luminescent copolymer were blended 90 parts by weight of a commercially available EVA resin as a different matrix resin, 1 part by weight of a crosslinking agent (2,5-dimethyl-2,5-di(t-butylperoxy)hexane), 0.3 part by weight of a silane coupling agent (γ-methacryloxypropyltrimethoxysilane), and 1 part by weight of a crosslinking aid (triallylisocyanate). The resultant was kneaded at 80° C., and then a hot press machine was used to make the kneaded material into a sheet at 80° C. In this way, a photovoltaic encapsulant sheet was yielded.

### Comparative Examples 2 to 11

The same manner as in Comparative Example 1 was perform to produce photovoltaic encapsulant sheets in which compounds (14) to (23) were used, respectively, instead of the compound (13).

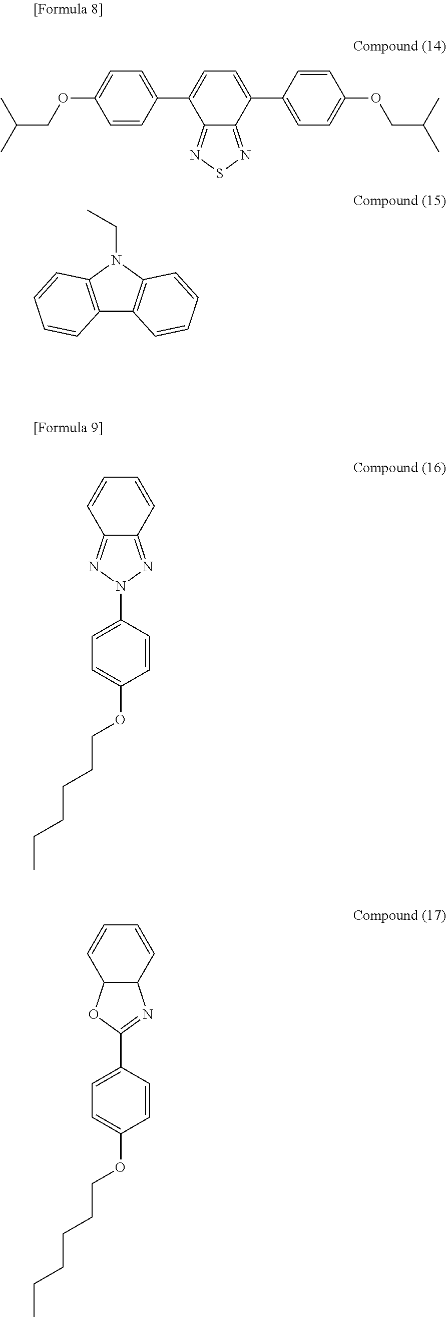 [SMILES: CC(C)COc1ccc(-c2ccc(-c3ccc(OCC(C)C)cc3)c3nsnc23)cc1 ; CCn1c2ccccc2c2ccccc21 ; CCCCCCOc1ccc(-n2nc3ccccc3n2)cc1 ; CCCCCCOc1ccc(C2=NC3C=CC=CC3O2)cc1]

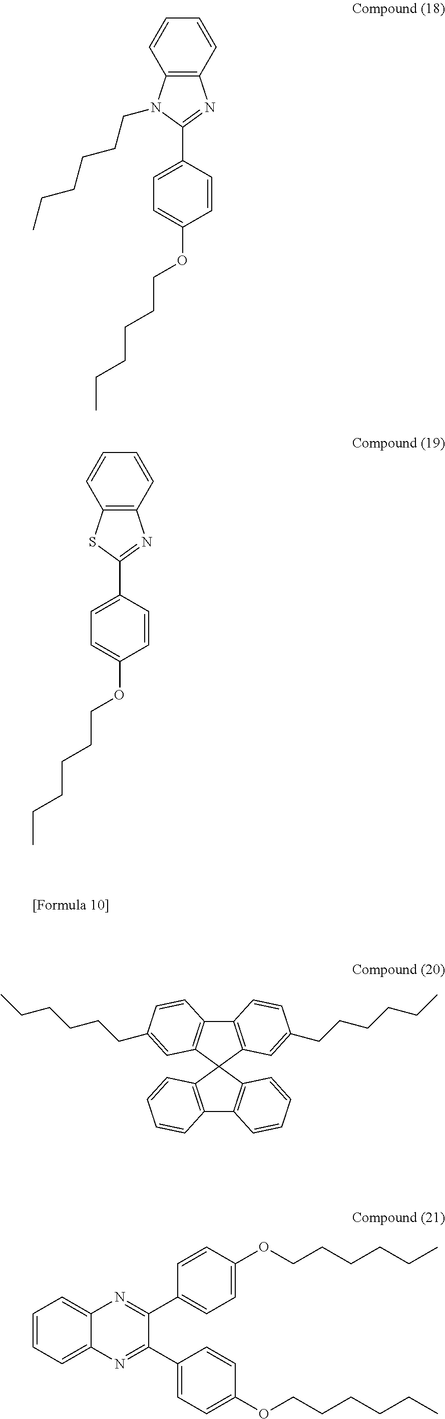

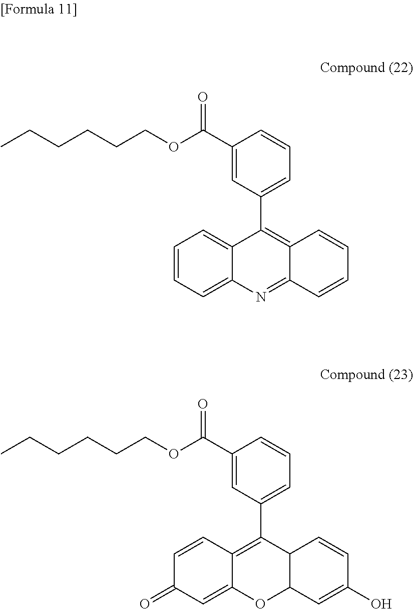 [SMILES: CCCCCCOC(=O)c1cccc(-c2c3ccccc3nc3ccccc23)c1 ; CCCCCCOC(=O)c1cccc(C2=C3C=CC(=O)C=C3OC3C=C(O)C=CC23)c1]

### Comparative Example 12

The same manner as in Comparative Example 1 was performed except that the compound (13) was not used, so as to produce a photovoltaic encapsulant sheet.

### (Measurement of Molecular Weight)

A GPC instrument (HLC-8220 GPC, manufactured by Tosoh Corp.) was used to measure the number-average molecular weight and the weight-average molecular weight of each of the polymers. Conditions for the measurement were as follows:
Sample concentration: 0.001% by weight (THF solution),
Sample injected volume: 10 μL,
Eluent: chloroform,
Flow rate: 0.3 mL/min,
Measurement temperature: 40° C.,
Columns: TSKgel, Super HZM-H/HZ2000/HZ1000, and
Detector: Differential refractor (RI).

Each of the molecular weights was gained as a value in terms of styrene.

### (Measurement of Maximum Absorption Wavelength, and Fluorescence Emission Wavelength)

Measurements were made about the maximum absorption wavelength and the fluorescence emission wavelength of the fluorescence emission compound used in each of the working examples and the comparative examples. The measurement of the maximum absorption wavelength was made, using an ultraviolet and visible spectrophotometer (V-560, manufactured by JASCO Corp.). The wavelength at which the maximum value was shown in the Abs measurement of the compound was measured.

The measurement of the fluorescence emission wavelength was made, using an instrument F-4500 manufactured by Hitachi High-Technologies Corp. The wavelength at which the maximum emission intensity was shown in the (excitation-emission) three-dimension measurement of the compound was measured.

### (Production of Each Solar Cell Module)

Each of the encapsulant sheets obtained as described above was cut into a size of 20×20 cm. The following were then put onto each other: a reinforced glass piece (SOLITE, manufactured by Asahi Glass Co., Ltd.) as a protective glass piece; the encapsulant sheet; a solar cell (of a crystal silicon type, Q6LTT3-G2-200/1700-A, manufactured by Hanwha Q CELLS Co., Ltd.); a encapsulant sheet (400-μm-thick EVA sheet) for a backside; and a PET film as a back sheet. A vacuum laminator (LM-50×50-S, manufactured by NPC Inc.) was used to laminate these members onto each other at 150° C. in a vacuum state for 5 minutes and a pressured state for 20 minutes to produce a solar cell module.

### (Measurement of Jsc of Each of Solar Cell Modules)

A spectral sensitivity measuring instrument (CEP-25RR, manufactured by JASCO Corp.) was used to measure the spectral sensitivity of each of the solar cell modules yielded as described above. The Jsc value thereof was obtained which was calculated out from the spectral sensitivity measurement. The Jsc value of any sample is the short circuit current density thereof that is calculated out by an arithmetic operation of the following two: a spectral sensitivity spectrum obtained by measuring the sample through a spectral sensitivity measuring instrument; and sunlight as a reference.

A measurement was made about the Jsc value of the solar cell module produced using the encapsulant sheet of each of Examples 1 and 13 and Comparative Example 12. As a result, the Jsc value of the solar cell module of Example 1 was larger than that of the solar cell module of Comparative Example 12 by 2.0%. Thus, the module of Example 1 was improved in photoelectric conversion efficiency. Moreover, the Jsc value of the solar cell module of Example 13 was larger than that of the solar cell module of Comparative Example 12 by 1.9%. Thus, the module of Example 13 was improved in photoelectric conversion efficiency.

### (Verification of Fixation Degree of Each of Dyes)

The encapsulant sheet of each of the working examples and the comparative examples was immersed in a solvent to be impregnated with the solvent. A spectrophotometer was used to measure the respective absorbance of the sheet before and after the elution-out test. A comparison was then made therebetween.

Each of the resultant encapsulant sheets, the weight of the sheet being 300 mg, was allowed to stand still in 50 mL of isopropyl alcohol at 40° C. for 4 hours, and then an evaluation was made as to whether or not the dye eluted out. Thereafter, the resultant encapsulant sheet was dried, and then the absorbance of the encapsulant sheet was measured at the maximum absorption wavelength of this sheet. About each of the sheets, a comparison was made between the respective absorbance, at the maximum absorption wavelength, before and after the elution experiment to calculate and evaluate the proportion of the dye fixed to the resin. As the fixation degree of the dye, a value calculated out in accordance with the following equation was used:

Fixation degree (%)={(absorbance after the elution test)/(absorbance before the elution test)}×100

The resultant results are shown in Table 1 described below.

TABLE 1

| | Compound | Fixation degree |
|---|---|---|
| Example 1 | Compound (1) | 98% |
| Example 2 | Compound (2) | 99% |
| Example 3 | Compound (3) | 98% |
| Example 4 | Compound (4) | 97% |
| Example 5 | Compound (5) | 96% |
| Example 6 | Compound (6) | 99% |
| Example 7 | Compound (7) | 95% |
| Example 8 | Compound (8) | 99% |
| Example 9 | Compound (9) | 98% |
| Example 10 | Compound (10) | 97% |
| Example 11 | Compound (11) | 98% |
| Example 12 | Compound (12) | 96% |
| Example 13 | Compound (1) | 95% |
| Comparative | Compound (13) | 3% |
| Example 1 | | |
| Comparative | Compound (14) | 7% |
| Example 2 | | |
| Comparative | Compound (15) | 4% |
| Example 3 | | |
| Comparative | Compound (16) | 2% |
| Example 4 | | |
| Comparative | Compound (17) | 5% |
| Example 5 | | |
| Comparative | Compound (18) | 8% |
| Example 6 | | |
| Comparative | Compound (19) | 9% |
| Example 7 | | |
| Comparative | Compound (20) | 4% |
| Example 8 | | |
| Comparative | Compound (21) | 3% |
| Example 9 | | |
| Comparative | Compound (22) | 7% |
| Example 10 | | |
| Comparative | Compound (23) | 5% |
| Example 11 | | |

As described above, in the sheet obtained in each of the working examples, the luminescent ethylene-based copolymer itself, which includes the fluorescent dye as a monomer, is a matrix material. Thus, even when the sheet is immersed into the solvent to be impregnated with the solvent, the dye does not easily elute out. Accordingly, about the luminescent ethylene-based copolymer of the present invention, and a encapsulant composition and a encapsulant layer each using this copolymer, the following has been understood: the absorbing/light-emitting properties of their chromophore are maintained; and further the dye is restrained from being shifted to the outside of the layer or the outside of the system, so that the dye is excellent in property of not being eluted out.

### DESCRIPTION OF REFERENCE SIGNS

1: Solar cell module
10: Surface protective layer
20: Wavelength-converting encapsulant layer
30: Solar cell
40: Backside encapsulant layer
50: Back sheet

1. A luminescent ethylene-based copolymer, comprising, as a monomer component, a fluorescent dye compound having an unsaturated bond.

2. The luminescent ethylene-based copolymer according to claim 1, wherein the unsaturated bond is a carbon-carbon double bond.

3. The luminescent ethylene-based copolymer according to claim 1, to which the fluorescent dye compound is bonded through a covalent bond.

4. The luminescent ethylene-based copolymer according to claim 1, wherein the copolymeric composition of the fluorescent dye compound is from 0.01 to 20% by weight.

5. The luminescent ethylene-based copolymer according to claim 1, wherein the fluorescent dye compound has a triazole skeleton, carbazole skeleton, thiadiazole skeleton, spiropyran skeleton, acridine skeleton, xanthene skeleton, imidazole skeleton, oxazole skeleton, quinoxaline skeleton, or thiazole skeleton.

6. The luminescent ethylene-based copolymer according to claim 1, comprising, as a monomer component, at least one of an α-olefin and vinyl acetate.

7. The luminescent ethylene-based copolymer according to claim 1, which has a maximum absorption wavelength in a range from 300 to 410 nm.

8. The luminescent ethylene-based copolymer according to claim 7, which has a maximum fluorescence emission wavelength in a range from 400 to 560 nm.

9. A photovoltaic encapsulant composition, comprising the luminescent ethylene-based copolymer according to claim 1.

10. A photovoltaic encapsulant layer, which is formed using the photovoltaic encapsulant composition according to claim 9.

11. A solar cell module, comprising a photovoltaic encapsulant layer formed using the photovoltaic encapsulant composition according to claim 9.

12. The solar cell module according to claim 11, which is configured to cause a light ray radiated into the module to pass through the photovoltaic encapsulant layer before the light ray reaches a solar cell of the module.

13. The solar cell module according to claim 11, which is configured to arrange the photovoltaic encapsulant layer as the photovoltaic encapsulant layer is positioned only at an incident-ray side of the solar cell.

14. The solar cell module according to any one of claim 11, wherein the solar cell is a crystal silicon solar cell.

15. A method for producing the luminescent ethylene-based copolymer recited in claim 1, comprising the step of polymerizing a monomer material comprising the fluorescent dye compound, which has an unsaturated bond, in the presence of a polymerization initiator.
